(19) United States
(12) Patent Application Publication
(10) Pub. No.: US 2023/0292452 A1
(43) Pub. Date: Sep. 14, 2023

(54) DISPLAY DEVICE AND MANUFACTURING METHOD THEREOF

(71) Applicant: Samsung Display Co., Ltd., Yongin-si (KR)

(72) Inventors: EUN-KYUNG YEON, Seongnam-si (KR); YI JOON AHN, Seoul (KR); JAEBEEN LEE, Seoul (KR); KANG YOUNG LEE, Seongnam-si (KR); MOONWON CHANG, Yongin-si (KR)

(21) Appl. No.: 17/992,234

(22) Filed: Nov. 22, 2022

(30) Foreign Application Priority Data
Mar. 8, 2022 (KR) 10-2022-0029040

(51) Int. Cl. H05K 5/02; H10K 71/00; B32B 7/12; B32B 3/16

(52) U.S. Cl. CPC H05K 5/0217; H01L 51/56; B32B 7/12; B32B 3/16; H01L 27/3244

(57) ABSTRACT

A display device includes a substrate including a first area, a second area, and a bending area between the first area and the second area, a light-emitting element disposed on the first area, a driver disposed on the second area, and a support part that is disposed under the substrate. A first opening and a plurality of second openings are defined in the support part. The first opening overlaps the bending area and the plurality of second openings overlap the first area.

This application claims priority to Korean Patent Application No. 10-2022-0029040, filed on Mar. 8, 2022, and all the benefits accruing therefrom under 35 U.S.C. § 119, the content of which in its entirety is herein incorporated by reference.

### BACKGROUND

### 1. Field

Embodiments of the disclosure described herein relate to a display device and a manufacturing method thereof.

### 2. Description of the Related Art

Electronic devices, such as a smart phone, a digital camera, a notebook computer, a car navigation unit, a smart television, and the like, which provide an image to a user include a display device for displaying an image. The display device generates an image and provides the generated image to the user through a display screen.

Recently, with a development of display device technology, various forms of display devices are being developed. Various flexible display devices that may be curved, folded, or rolled have been developed, for example. The flexible display devices may be easy to carry and may improve user convenience.

A flexible display device includes a flexible display panel, a shape of which is diversely changed, and a support part for supporting the flexible display panel. The support part may support the flexible display panel when the flexible display panel is unrolled.

### SUMMARY

Embodiments of the disclosure provide a display device having a simplified structure and a simplified manufacturing process and a method of manufacturing the display device.

In an embodiment of the disclosure, a display device includes a substrate including a first area, a second area, and a bending area between the first area and the second area, a light-emitting element disposed on the first area, a driver disposed on the second area, and a support part that is disposed under the substrate. A first opening and a plurality of second openings are defined in the support part. The first opening overlaps the bending area and the plurality of second openings overlaps the first area.

In an embodiment of the disclosure, a display device includes a substrate including a first area, a second area, and a bending area between the first area and the second area, a pixel disposed on the first area, a driver disposed on the second area, and a support part that is disposed under the substrate. A first opening is defined in the support part and overlaps the bending area. The support part includes a surface facing the substrate and including a first partial surface adjacent to the first opening and a second partial surface around the first partial surface. The first partial surface of the support part adjacent to the first opening is inclined with respect to the second partial surface around the first partial surface.

In an embodiment of the disclosure, a method for manufacturing a display device includes changing physical properties of a first portion and a plurality of second portions of a support part, providing a substrate on the support part, providing a pixel on an area of the substrate that overlaps the plurality of second portions, and defining a first opening and a plurality of second openings in the support part by removing the first portion and the plurality of second portions.

### BRIEF DESCRIPTION OF THE DRAWINGS

The above and other objects and features of the disclosure will become apparent by describing in detail embodiments thereof with reference to the accompanying drawings.

FIG. 1 is a perspective view of an embodiment of a display device according to the disclosure.

FIG. 2 is a view illustrating a display module accommodated in a housing illustrated in FIG. 1.

FIG. 3 is a view illustrating a rolled state of the display module illustrated in FIG. 2.

FIGS. 4 and 5 are views illustrating the display module exposed outside the housing illustrated in FIG. 1.

FIG. 6 is a view illustrating a section of the display module illustrated in FIG. 2.

FIG. 7 is a view illustrating a section of a display panel illustrated in FIG. 6.

FIG. 8 is a plan view of the display panel illustrated in FIG. 6.

FIG. 9 is a cross-sectional view of the display device corresponding to line I-I′ illustrated in FIG. 8.

FIGS. 10 and 11 are views illustrating embodiments of a support part illustrated in FIG. 9.

FIG. 12 is a view illustrating a state in which a bending area illustrated in FIG. 9 is bent.

FIG. 13 is a view illustrating a state in which the display panel illustrated in FIG. 12 is fixed to a roller.

FIG. 14 is a view illustrating a state in which a first area of the display panel illustrated in FIG. 13 is rolled around the roller.

FIG. 15 is a view illustrating an embodiment of a configuration of a display device according to the disclosure.

FIG. 16 is an enlarged view of a bending area and a portion of a support part under the bending area illustrated in FIG. 15.

FIG. 17 is a view illustrating a state in which the bending area illustrated in FIG. 15 is bent.

FIGS. 18 to 23 are views for describing a manufacturing method of the display device illustrated in FIG. 9.

FIGS. 24 to 28 are views for describing a manufacturing method of the display device illustrated in FIG. 15.

### DETAILED DESCRIPTION

In this specification, when it is mentioned that a component (or, an area, a layer, a part, etc.) is referred to as being “on”, “connected to” or “coupled to” another component, this means that the component may be directly on, connected to, or coupled to the other component or a third component may be present therebetween.

Identical reference numerals refer to identical components. Additionally, in the drawings, the thicknesses, proportions, and dimensions of components are exaggerated for effective description.

As used herein, the term “and/or” includes all of one or more combinations defined by related components.

Terms such as first, second, and the like may be used to describe various components, but the components should not be limited by the terms. The terms may be used only for distinguishing one component from other components. Without departing the scope of the present disclosure, a first component may be referred to as a second component, and similarly, the second component may also be referred to as the first component, for example. The terms of a singular form may include plural forms unless otherwise specified.

In addition, terms such as “below”, “under”, “above”, and “over” are used to describe a relationship of components illustrated in the drawings. The terms are relative concepts and are described based on directions illustrated in the drawing.

Unless otherwise defined, all terms used herein, including technical or scientific terms, have the same meanings as those generally understood by those skilled in the art to which the disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the application.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

Hereinafter, embodiments of the disclosure will be described with reference to the accompanying drawings.

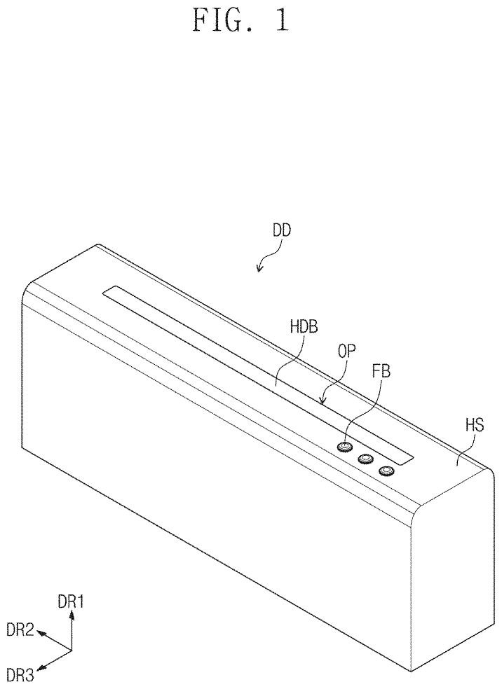

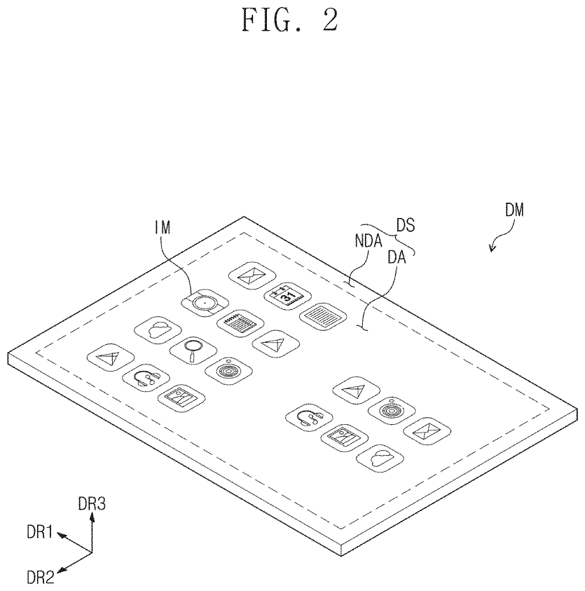

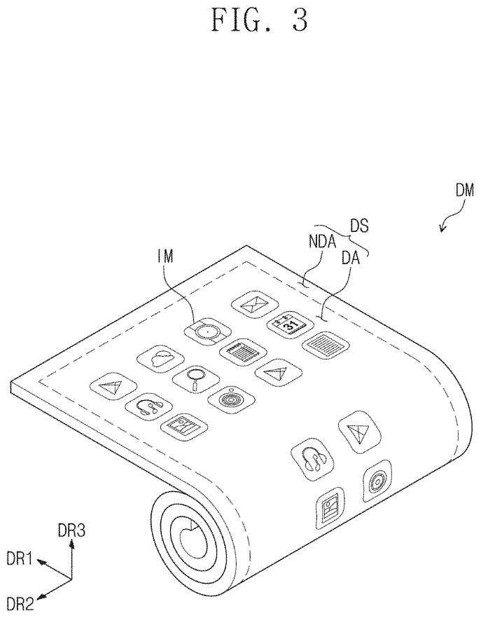

FIG. 1 is a perspective view of an embodiment of a display device according to the disclosure. FIG. 2 is a view illustrating a display module accommodated in a housing illustrated in FIG. 1. FIG. 3 is a view illustrating a rolled state of the display module illustrated in FIG. 2.

Referring to FIGS. 1 and 2, the display device DD may include the housing HS, a head bar HDB, the display module DM, and a plurality of function buttons FB.

An opening OP that is open in a first direction DR1 may be defined in the housing HS. The housing HS may extend longer in a second direction DR2 crossing the first direction DR1 than in the first direction DR1.

Hereinafter, a direction crossing a plane defined by the first and second directions DR1 and DR2 is defined as a third direction DR3. The housing HS may extend longer in the second direction DR2 than in the third direction DR3.

The head bar HDB may be disposed in the opening OP. The head bar HDB may move toward or away from the housing HS in the first direction DR1.

The display module DM may be accommodated in the housing HS. The display module DM may have a plane defined by the first and second directions DR1 and DR2. The display module DM may have a quadrangular (e.g., rectangular) shape with long sides extending in the first direction DR1 and short sides extending in the second direction DR2. However, without being limited thereto, the display module DM may have various shapes such as a circular shape, a polygonal shape, or the like.

The upper surface of the display module DM may be defined as a display surface DS and may have a plane defined by the first direction DR1 and the second direction DR2. Images IM generated by the display module DM may be provided to a user through the display surface DS.

The display surface DS may include a display area DA and a non-display area NDA around the display area DA. The display area DA may display an image, and the non-display area NDA may not display an image. The non-display area NDA may surround the display area DA and may define the border of the display module DM that is printed in a predetermined color.

The function buttons FB may be disposed on the upper surface of the housing HS. The function buttons FB may provide various functions to the display device DD. In an embodiment, the display module DM disposed inside the housing HS may be moved outside the housing HS by the function buttons FB, or the display module DM outside the housing HS may be moved into the housing HS by the function buttons FB, for example. In addition, the luminance and definition of an image displayed on the display module DM may be controlled by the function buttons FB.

Referring to FIG. 3, the display module DM may be a flexible display module. The display module DM may be rolled into the shape of a roll. The display module DM may be rolled in the first direction DR1. The display module DM may be rolled from one side of the display module DM. The display module DM may be rolled such that the display surface DS faces toward the outside.

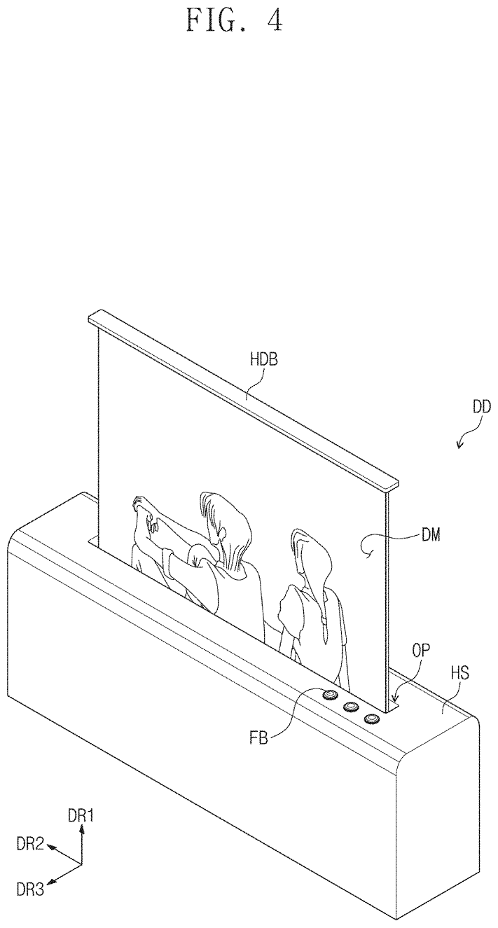

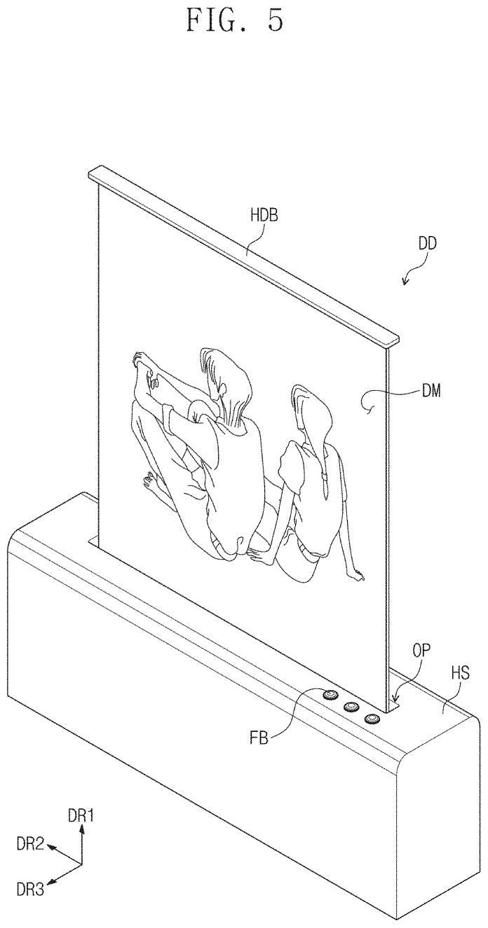

FIGS. 4 and 5 are views illustrating the display module exposed outside the housing illustrated in FIG. 1.

Referring to FIGS. 4 and 5, the top of the display module DM in the first direction DR1 may be connected to the head bar HDB. As the head bar HDB moves away from the housing HS in the first direction DR1, the display module DM may be extracted from the housing HS to the outside through the opening OP. Accordingly, the display module DM may be extended and exposed outside the housing HS.

In contrast, when the head bar HDB moves toward the housing HS in the first direction DR1, the display module DM may be retracted into the housing HS through the opening OP as illustrated in FIG. 1. Accordingly, the display module DM may be disposed inside the housing HS and may not be exposed to the outside.

An operation of extending the display module DM outside the housing HS may be performed by an up button (reference numeral not being illustrated) among the function buttons FB. An operation of retracting the display module DM into the housing HS may be performed by a down button (reference numeral not being illustrated) among the function buttons FB. The area of an exposed surface of the display module DM may be diversely adjusted by the up button and the down button. However, the disclosure is not limited thereto, and the area of the exposed surface of the display module DM may be diversely adjusted by a remote control.

Although not illustrated, a lifting part for extension and retraction of the display module DM may be disposed on the rear surface of the display module DM.

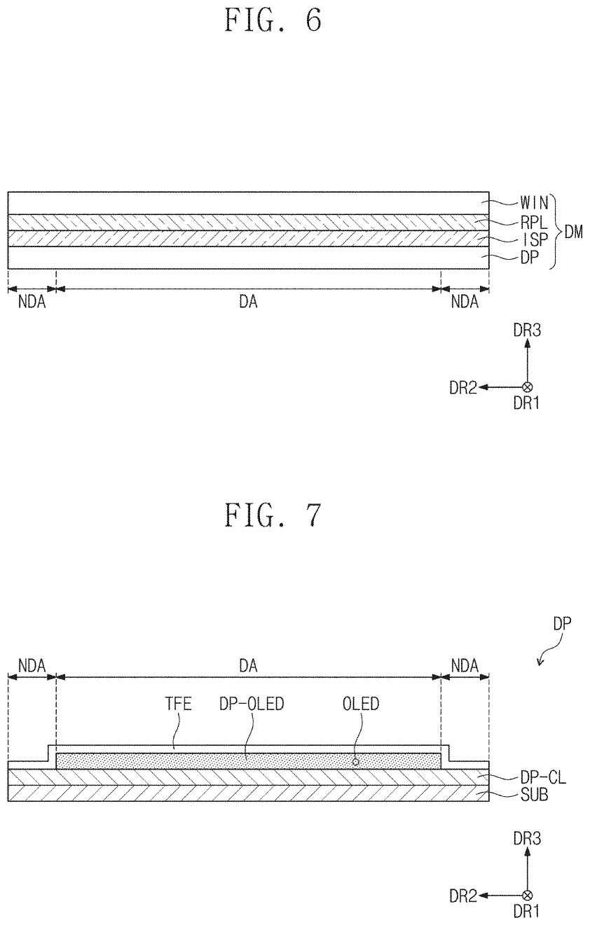

FIG. 6 is a view illustrating a section of the display module illustrated in FIG. 2.

In FIG. 6, a section of the display module DM viewed in the first direction DR1 is illustrated.

Referring to FIG. 6, the display module DM may include a display panel DP, an input sensing part ISP, an anti-reflection layer RPL, and a window WIN.

The display panel DP may be a flexible display panel. The display panel DP in an embodiment of the disclosure may be an emissive display panel and is not particularly limited. In an embodiment, the display panel DP may be an organic light-emitting display panel or an inorganic light-emitting display panel, for example. An emissive layer of the organic light-emitting display panel may include an organic light-emitting material. An emissive layer of the inorganic light-emitting display panel may include quantum dots, quantum rods, or the like. Hereinafter, it will be exemplified that the display panel DP is an organic light-emitting display panel.

The input sensing part ISP may be disposed on the display panel DP. The input sensing part ISP may include a plurality of sensor parts (not illustrated) for sensing an external input in a capacitive manner. The input sensing part ISP may be directly manufactured on the display panel DP when the display module DM is manufactured. However, without being limited thereto, the input sensing part ISP may be manufactured as a panel separate from the display panel DP and may be attached to the display panel DP by an adhesive layer.

The anti-reflection layer RPL may be disposed on the input sensing part ISP. The anti-reflection layer RPL may be directly formed on the input sensing part ISP, or may be coupled to the input sensing part ISP by an adhesive layer. The anti-reflection layer RPL may be defined as a film for preventing reflection of external light. The anti-reflection layer RPL may decrease the reflectivity of external light incident toward the display panel DP from above the display device DD.

When external light travelling toward the display panel DP is reflected from the display panel DP and provided back to the user, the user may visually recognize the external light as in a mirror. To prevent such a phenomenon, the anti-reflection layer RPL may include a plurality of color filters that display the same colors as pixels of the display panel DP.

The color filters may filter external light to the same colors as the pixels. In this case, the external light may not be visible to the user. However, without being limited thereto, the anti-reflection layer RPL may include a polarizer film for decreasing the reflectivity of external light. The polarizer film may include a phase retarder and/or a polarizer.

The window WIN may be disposed on the anti-reflection layer RPL. The window WIN may be directly formed on the anti-reflection layer RPL, or may be coupled to the anti-reflection layer RPL by an adhesive layer. The window WIN may protect the display panel DP, the input sensing part ISP, and the anti-reflection layer RPL from external scratches and impacts.

FIG. 7 is a view illustrating a section of the display panel illustrated in FIG. 6.

In FIG. 7, a section of the display panel DP viewed in the first direction DR1 is illustrated.

Referring to FIG. 7, the display panel DP may include a substrate SUB, a circuit element layer DP-CL disposed on the substrate SUB, a display element layer DP-OLED disposed on the circuit element layer DP-CL, and a thin-film encapsulation layer TFE disposed on the display element layer DP-OLED.

The substrate SUB may include a display area DA and a non-display area NDA around the display area DA. The substrate SUB may include a flexible plastic material such as polyimide (“PI”). The display element layer DP-OLED may be disposed on the display area DA.

A plurality of pixels may be disposed on the display area DA. Each of the pixels may include a light-emitting element OLED connected to a transistor in the circuit element layer DP-CL and disposed in the display element layer DP-OLED.

The thin-film encapsulation layer TFE may be disposed on the circuit element layer DP-CL to cover the display element layer DP-OLED. The thin-film encapsulation layer TFE may include inorganic layers and an organic layer between the inorganic layers. The inorganic layers may protect the pixels from moisture/oxygen. The organic layer may protect the pixels from foreign matter such as dust particles.

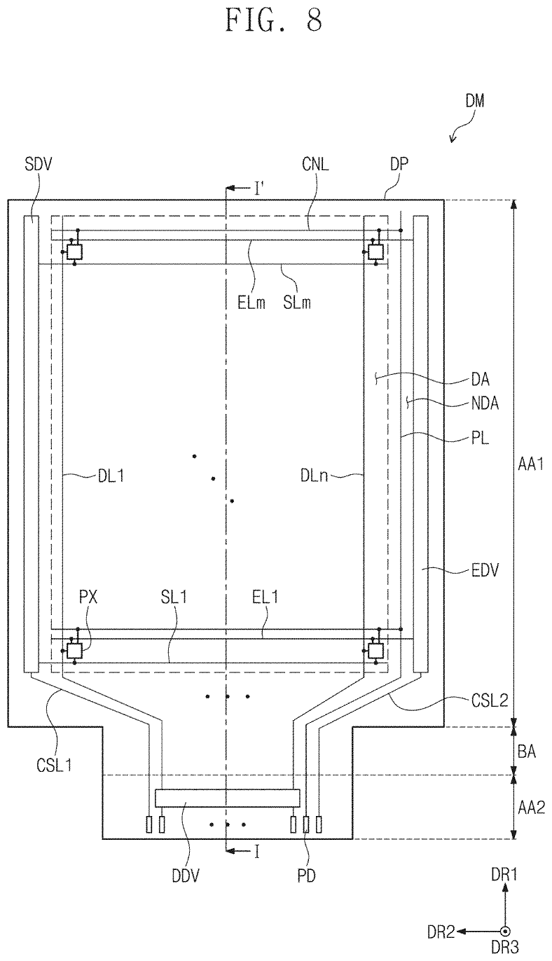

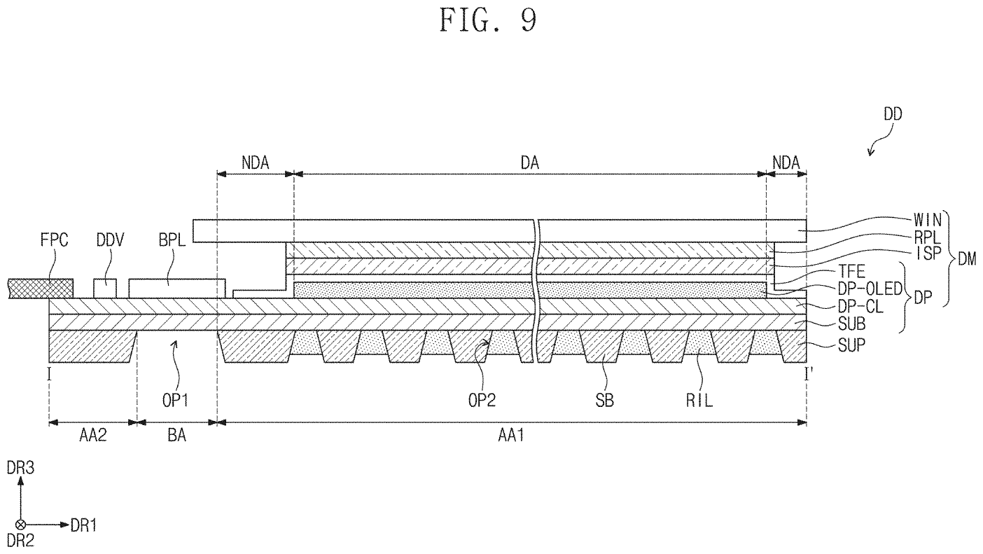

FIG. 8 is a plan view of the display panel illustrated in FIG. 6.

Referring to FIG. 8, the display module DM may include the display panel DP, a scan driver SDV, a data driver DDV, and a light emission driver EDV.

The display panel DP may include a first area AA1, a second area AA2, and a bending area BA between the first area AA1 and the second area AA2. The bending area BA may extend in the second direction DR2, and the first area AA1, the bending area BA, and the second area AA2 may be arranged in the first direction DR1.

The first area AA1 may include a display area DA and a non-display area NDA around the display area DA. The non-display area NDA may surround the display area DA. The display area DA may be an area that displays an image, and the non-display area NDA may be an area that does not display an image. The second area AA2 and the bending area BA may be areas that do not display an image.

The display panel DP may include a plurality of pixels PX, a plurality of scan lines SL1 to SLm, a plurality of data lines DL1 to DLn, a plurality of light emission lines EL1 to ELm, first and second control lines CSL1 and CSL2, a power line PL, a plurality of connecting lines CNL, and a plurality of pads PD. Here, “m” and “n” are natural numbers. The pixels PX may be disposed in the display area DA and may be connected to the scan lines SL1 to SLm, the data lines DL1 to DLn, and the light emission lines EL1 to ELm.

The scan driver SDV and the light emission driver EDV may be disposed in the non-display area NDA. The scan driver SDV and the light emission driver EDV may be disposed in the non-display areas NDA adjacent to opposite sides of the first area AA1 that face away from each other in the second direction DR2. The data driver DDV may be disposed in the second area AA2. The data driver DDV may be manufactured in the form of an integrated circuit chip and may be disposed (e.g., mounted) on the second area AA2.

The scan lines SL1 to SLm may extend in the second direction DR2 and may be connected to the scan driver SDV. The data lines DL1 to DLn may extend in the first direction DR1 and may be connected to the data driver DDV via the bending area BA. The light emission lines EL1 to ELm may extend in the second direction DR2 and may be connected to the light emission driver EDV.

The power line PL may extend in the first direction DR1 and may be disposed in the non-display area NDA. The power line PL may be disposed between the display area DA and the light emission driver EDV. However, without being limited thereto, the power line PL may be disposed between the display area DA and the scan driver SDV.

The power line PL may extend to the second area AA2 via the bending area BA. The power line PL may extend toward a lower end of the second area AA2 in the plan view. The power line PL may receive a drive voltage. The expression “in the plan view” used herein may mean that it is viewed in third direction DR3.

The connecting lines CNL may extend in the second direction DR2 and may be arranged in the first direction DR1. The connecting lines CNL may be connected to the power line PL and the pixels PX. The drive voltage may be applied to the pixels PX through the power line PL and the connecting lines CNL connected with each other.

The first control line CSL1 may be connected to the scan driver SDV and may extend toward the lower end of the second area AA2 via the bending area BA. The second control line CSL2 may be connected to the light emission driver EDV and may extend toward the lower end of the second area AA2 via the bending area BA. The data driver DDV may be disposed between the first control line CSL1 and the second control line CSL2.

The pads PD may be disposed adjacent to the lower end of the second area AA2 in the plan view. The data driver DDV, the power line PL, the first control line CSL1, and the second control line CSL2 may be connected to the pads PD.

The data lines DL1 to DLn may be connected to the corresponding pads PD through the data driver DDV. In an embodiment, the data lines DL1 to DLn may be connected to the data driver DDV, and the data driver DDV may be connected to the pads PD corresponding to the data lines DL1 to DLn, for example.

A printed circuit board (“PCB”) may be connected to the pads PD, and a timing controller and a voltage generator may be disposed on the PCB. The timing controller may be manufactured in the form of an integrated circuit chip and may be disposed (e.g., mounted) on the PCB. The timing controller and the voltage generator may be connected to the pads PD through the PCB.

The timing controller may control operations of the scan driver SDV, the data driver DDV, and the light emission driver EDV. The timing controller may generate a scan control signal, a data control signal, and a light emission control signal in response to control signals received from the outside. The voltage generator may generate the drive voltage.

The scan control signal may be provided to the scan driver SDV through the first control line CSL1. The light emission control signal may be provided to the light emission driver EDV through the second control line CSL2. The data control signal may be provided to the data driver DDV. The timing controller may receive image signals from the outside, may convert the data format of the image signals according to the specification of an interface with the data driver DDV, and may provide the converted signals to the data driver DDV.

The scan driver SDV may generate a plurality of scan signals in response to the scan control signal. The scan signals may be applied to the pixels PX through the scan lines SL1 to SLm. The scan signals may be sequentially applied to the pixels PX.

The data driver DDV may generate a plurality of data voltages corresponding to the image signals in response to the data control signal. The data voltages may be applied to the pixels PX through the data lines DL1 to DLn. The light emission driver EDV may generate a plurality of light emission signals in response to the light emission control signal. The light emission signals may be applied to the pixels PX through the light emission lines EL1 to ELm.

The pixels PX may receive the data voltages in response to the scan signals. The pixels PX may display an image by emitting light having luminance corresponding to the data voltages in response to the light emission signals. Light emission time of the pixels PX may be controlled by the light emission signals.

FIG. 9 is a cross-sectional view of the display device corresponding to line I-I′ illustrated in FIG. 8.

Referring to FIG. 9, the display device DD may include the display module DM and a support part SUP under the display module DM. Under the display module DM, the support part SUP may support the display module DM.

Likewise to the display panel DP, the substrate SUB may include a first area AA1, a second area AA2, and a bending area BA between the first area AA1 and the second area AA2. The display element layer DP-OLED may be disposed on the first area AA1. Light-emitting elements OLED disposed in the above-described display element layer DP-OLED may be disposed on the first area AA1.

The thin-film encapsulation layer TFE may be disposed on the first area AA1 to cover the display element layer DP-OLED. The input sensing part ISP may be disposed on the thin-film encapsulation layer TFE. The input sensing part ISP, the anti-reflection layer RPL, and the window WIN may be sequentially disposed on the first area AA1. The window WIN may extend above the bending area BA.

The data driver DDV may be disposed on the second area AA2. The data driver DDV may be defined as a driver. The circuit element layer DP-CL may be disposed on the first area AA1 and may extend above the bending area BA and the second area AA2. The data driver DDV may be disposed on the circuit element layer DP-CL.

The above-described data lines DL1 to DLn may be disposed in the circuit element layer DP-CL and may be connected to the data driver DDV. The above-described pads PD may be disposed in the circuit element layer DP-CL and may be connected to the data driver DDV.

A circuit board FPC may be disposed on one side of the second area AA2. The circuit board FPC may be defined as a flexible printed circuit board (“FPCB”). Although not illustrated, the timing controller and the voltage generator described above may be disposed on the circuit board FPC.

A bending protection layer BPL may be disposed on the bending area BA. The bending protection layer BPL may be further disposed on a portion of the first area AA1 that is adjacent to the bending area BA and a portion of the second area AA2 that is adjacent to the bending area BA. The bending protection layer BPL may include an acrylate-based resin or a urethane-based resin.

The bending protection layer BPL may serve to protect the bending area BA. The bending protection layer BPL may cover and protect lines disposed in the bending area BA. The bending protection layer BPL may complement the stiffness of the bending area BA and may prevent cracks in the bending area BA when the bending area BA is bent. The bending protection layer BPL may protect the bending area BA from an external impact.

The support part SUP may be disposed under the substrate SUB. The support part SUP disposed under the substrate SUB may support the display panel DP. In an embodiment, the support part SUP may include glass, for example. However, the material of the support part SUP is not limited thereto. The support part SUP may be directly attached to the substrate SUB. The upper surface of the support part SUP may be attached to the substrate SUB by directly contacting the lower surface of the substrate SUB. The upper surface of the support part SUP and the lower surface of the substrate SUB may be defined as surfaces facing each other.

A first opening OP1 and a plurality of second openings OP2 may be defined in the support part SUP. In the plan view, the first opening OP1 may overlap the bending area BA, and the second openings OP2 may overlap the first area AA1. The first opening OP1 may be defined under the bending area BA, and the second openings OP2 may be spaced apart from the first opening OP1 in the first direction DR1 and may be defined under the first area AA1. The first opening OP1 and the second openings OP2 may be defined in the same layer.

The second openings OP2 may be arranged in the first direction DR1. The first opening OP1 and the second openings OP2 may have a trapezoidal shape when viewed in the second direction DR2. Accordingly, portions of the support part SUP between the first and second openings OP1 and OP2 may have an inverted trapezoidal shape. Based on the first direction DR1, the width of the first opening OP1 may be greater than the width of each of the second openings OP2.

The display device DD may further include a plurality of resin layers RIL disposed in the second openings OP2. The resin layers RIL may not be disposed in the first opening OP1. The resin layers RIL may include a polymer resin. The resin layers RIL may include a thermosetting resin or a photo-curable resin.

The resin layers RIL in the second openings OP2 may contact the lower surface of the substrate SUB. The resin layers RIL may directly contact the lower surface of the substrate SUB. Because the resin layers RIL are disposed in the second openings OP2, the flat upper surface of the support part SUP may be provided under the first area AA1. The resin layers RIL may be more flexible than the support part SUP. That is, the support part SUP may have a higher modulus than a modulus of the resin layers RIL.

The lower surface of each of the resin layers RIL may be closer to the substrate SUB than the lower surface of the support part SUP is. The lower surface of the support part SUP may be defined as a surface facing away from the upper surface of the support part SUP. The lower surfaces of the resin layers RIL may be defined as surfaces facing away from the upper surfaces of the resin layers RIL. In an embodiment, based on the third direction DR3, the thickness of each of the resin layers RIL may be smaller than the thickness of the support part SUP and may be greater than or equal to one-half the thickness of the support part SUP, for example.

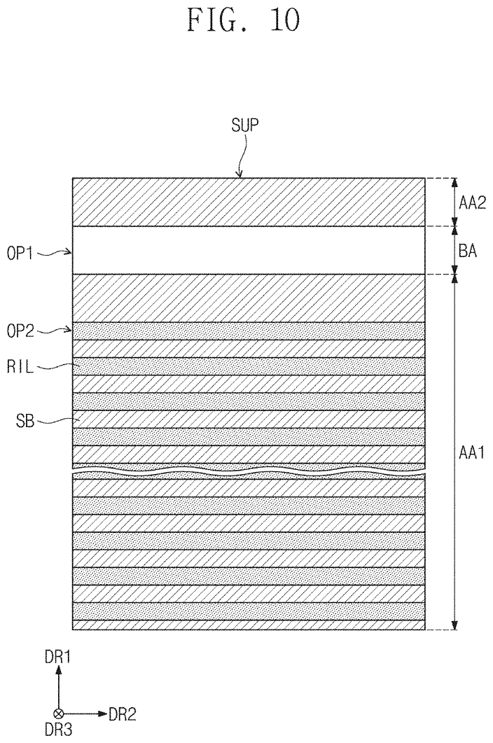

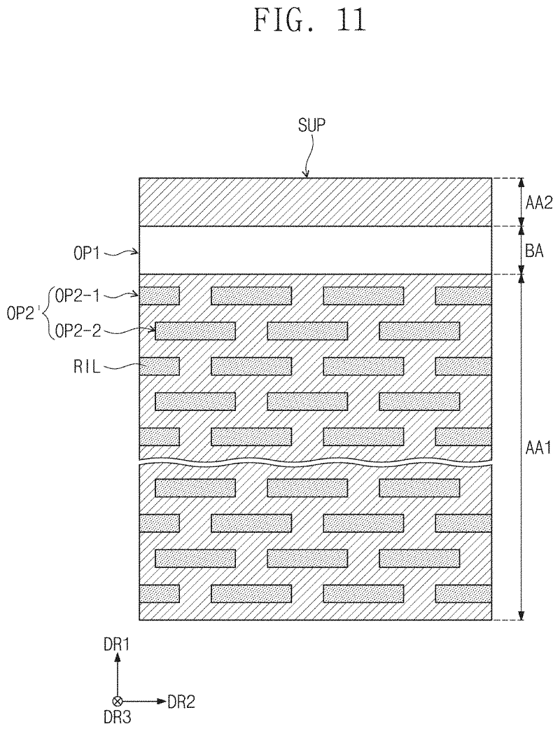

FIGS. 10 and 11 are views illustrating embodiments of the support part illustrated in FIG. 9.

Referring to FIG. 10, the first and second openings OP1 and OP2 may be defined in the support part SUP. The first opening OP1 may be defined on the bending area BA and may extend in the second direction DR2. The second openings OP2 may be defined on the first area AA1. The second openings OP2 may be arranged in the first direction DR1 and may extend in the second direction DR2.

On the first area AA1, the support part SUP may be divided by the second openings OP2. The support part SUP may include a plurality of support bars SB separated from one another by the second openings OP2. The support bars SB may extend in the second direction DR2 and may be arranged in the first direction DR1. The support bars SB may overlap the first area AA1 in the plan view.

Referring to FIGS. 9 and 10, the portion of the support part SUP that overlaps the bending area BA may be removed to define the first opening OP1, and thus the flexibility of the bending area BA may be increased, as compared with when the support part SUP is attached to the bending area BA. For a similar reason, the portions of the support part SUP that overlap the first area AA1 may be removed to define the second openings OP2, and thus the flexibility of the first area AA1 may be increased.

Referring to FIG. 11, the support part SUP may have first and second openings OP1 and OP2′ defined therein. The first opening OP1 may be defined on the bending area BA, and the second openings OP2′ may be defined on the first area AA1. The second openings OP2′ may be arranged in the first direction DR1 and the second direction DR2.

The second openings OP2′ may include a plurality of first sub-openings OP2-1 arranged in the second direction DR2 and a plurality of second sub-openings OP2-2 arranged in the second direction DR2 and adjacent to the first sub-openings OP2-1 in the first direction DR1.

In an embodiment, the second direction DR2 may correspond to rows, for example. The first sub-openings OP2-1 may be arranged in the h^{th} row, and the second sub-openings OP2-2 may be arranged in the (h+1)^{th} row. Here, “h” is a natural number. The second sub-openings OP2-2 may be staggered with respect to the first sub-openings OP2-1.

The portions of the support part SUP that overlap the first area AA1 may be removed to define the first sub-openings OP2-1 and the second sub-openings OP2-2, and thus the flexibility of the first area AA1 may be increased.

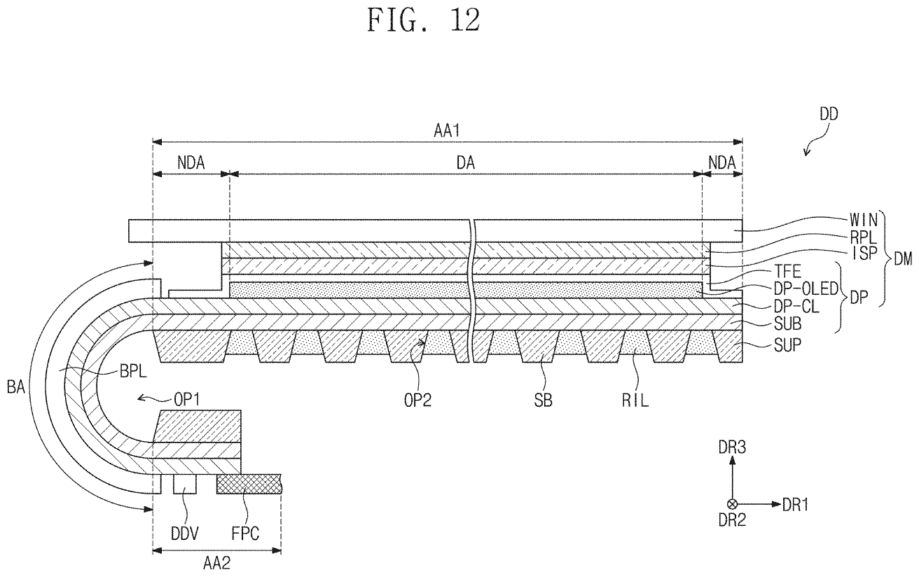

FIG. 12 is a view illustrating a state in which the bending area illustrated in FIG. 9 is bent.

Referring to FIGS. 9 and 12, the bending area BA may be bent such that the second area AA2 is disposed under the first area AA1. Accordingly, the data driver DDV may be disposed under the first area AA1. The portion of the support part SUP on the second area AA2 may also be disposed under the first area AA1. The bending protection layer BPL may be bent together with the bending area BA.

The bending area BA may be bent to be convex toward the outside of the display panel DP. The bending area BA may be bent to have a predetermined curvature. The bending area BA may be easily bent because the support part SUP is not disposed under the bending area BA and the first opening OP1 is defined under the bending area BA. In FIG. 12, the data driver DDV may be disposed under the second area AA2.

The second area AA2 and the bending area BA that do not display an image may be defined as a bezel area. The bezel area of the display panel DP may be minimized in the plan view because the second area AA2 is disposed under the first area AA1.

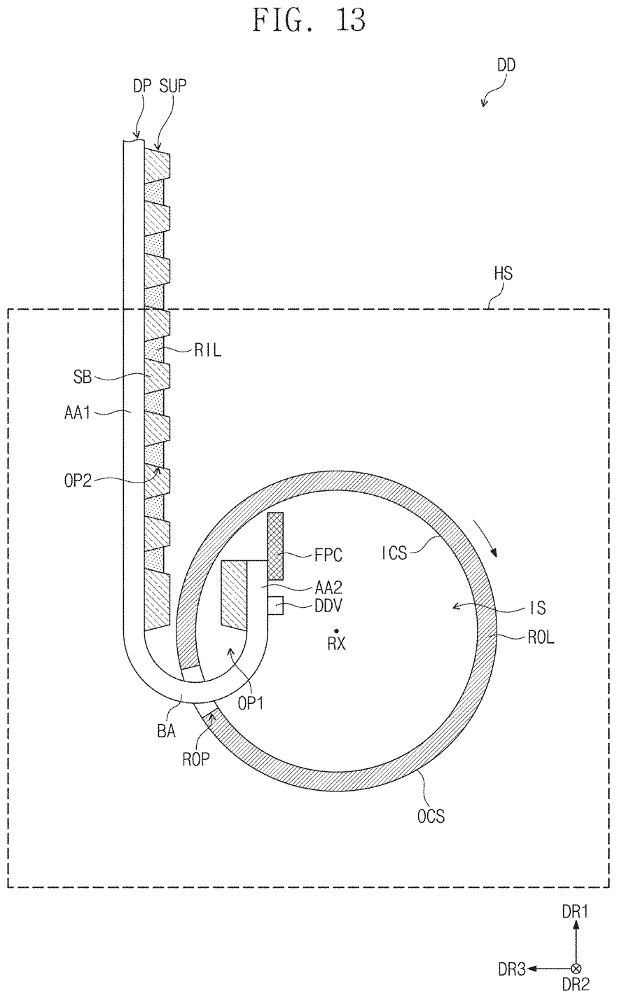

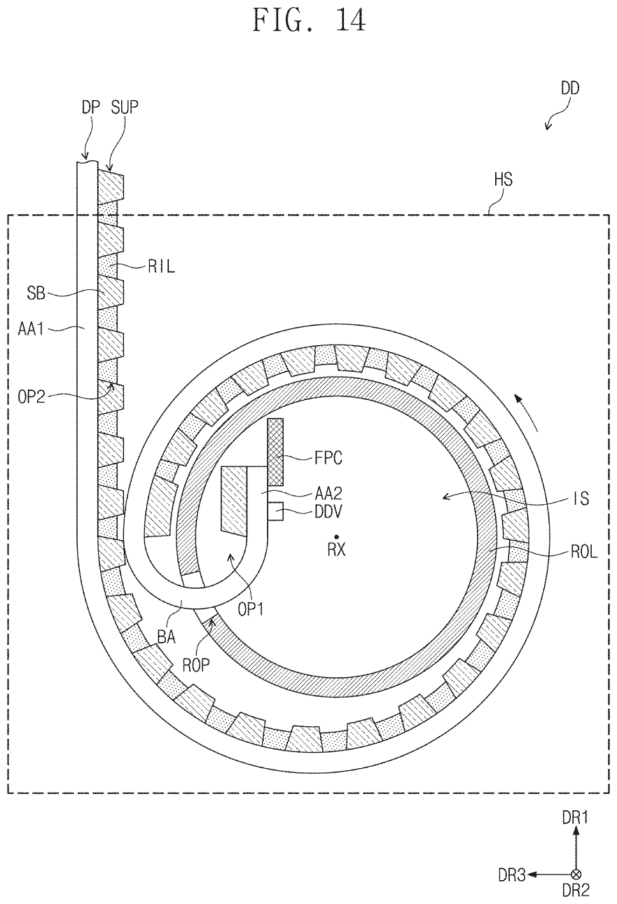

FIG. 13 is a view illustrating a state in which the display panel illustrated in FIG. 12 is fixed to a roller. FIG. 14 is a view illustrating a state in which the first area of the display panel illustrated in FIG. 13 is rolled around the roller.

In FIGS. 13 and 14, the housing HS is schematically illustrated by dotted lines, the display panel DP is illustrated as a single layer, and the components on the display panel DP are omitted. Hereinafter, the support part SUP illustrated in FIGS. 13 and 14 will be described as a structure including the support bars SB illustrated in FIG. 10.

Referring to FIGS. 13 and 14, the display device DD may include the roller ROL disposed in the housing HS. The roller ROL may have a circular shape when viewed in the second direction DR2. Substantially, the roller ROL may have a cylindrical shape extending in the second direction DR2. The roller ROL may rotate in the clockwise or counterclockwise direction about an axis of rotation RX parallel to the second direction DR2.

Although not illustrated, the display device DD may further include an actuator for rotating the roller ROL.

A space IS (hereinafter, also referred to as the inner space) may be defined inside the roller ROL. An opening ROP fluidly connected with the inner space IS may be defined in the roller ROL. The opening ROP may be defined through the roller ROL from the outer circumferential surface OCS of the roller ROL to the inner circumferential surface ICS of the roller ROL. The inner circumferential surface ICS of the roller ROL may define the opening ROP, and the outer circumferential surface OCS of the roller ROL may be defined as a surface facing away from the inner circumferential surface ICS of the roller ROL.

When the bending area BA is bent and the second area AA2 faces the first area AA1, the second area AA2 may be disposed in the inner space IS, and the bending area BA may be disposed in the opening ROP. Depending on this structure, one side of the display panel DP may be fixed to the roller ROL.

The first area AA1 may be disposed outside the roller ROL. As the roller ROL rotates, the first area AA1 may be disposed inside the housing HS, or may be extracted from the housing HS to the outside.

Referring to FIG. 13, the first area AA1 may be unrolled from the roller ROL when the roller ROL rotates about the axis of rotation RX in the clockwise direction. The first area AA1 may be unrolled from the roller ROL and may be extracted from the housing HS to the outside.

Referring to FIG. 14, the first area AA1 may be rolled around the roller ROL when the roller ROL rotates about the axis of rotation RX in the counterclockwise direction. Because the second openings OP2 overlapping the first area AA1 are defined in the support part SUP, the flexibility of the first area AA1 may be improved, and thus the first area AA1 may be more easily rolled around the roller ROL.

The first area AA1 may be introduced into the housing HS by being rolled around the roller ROL. When the first area AA1 is rolled around the roller ROL to the maximum, the first area AA1 may be disposed inside the housing HS without being exposed to the outside.

Referring to FIGS. 13 and 14, depending on the above-described structure, the first area AA1 may be rolled or unrolled in the first direction DR1 by the roller ROL.

The support bars SB having a higher modulus may support the first area AA1. The resins layers RIL between the support bars SB may fill the second openings OP2 between the support bars SB, and thus the support part SUP under the first area AA1 may have a flat surface.

When the resin layers RIL are not disposed in the second openings OP2, the portions of the first area AA1 that overlap the second openings OP2 may sag downward toward the support part SUP. Accordingly, the degree of flatness of the first area AA1, which displays an image, may be degraded. The degree of flatness may be defined as surface quality.

However, because the resin layers RIL are disposed in the second openings OP2 in the embodiment of the disclosure, the support part SUP may provide a flat upper surface under the first area AA1. Accordingly, the surface quality of the first area AA1, which displays an image, may be improved.

When the first area AA1 is rolled around the roller ROL, the gaps between the support bars SB may be decreased so that the second openings OP2 may be narrowed. When the resin layers RIL are disposed to the lower surface of the support part SUP, the resin layers RIL may protrude outward from the lower surface of the support part SUP because the second openings OP2 are narrowed when the first area AA1 is rolled around the roller ROL.

However, in an embodiment of the disclosure, the resin layers RIL may be disposed in the second openings OP2 such that the lower surfaces of the resin layers RIL are disposed in a higher position than a position of the lower surface of the support part SUP. In this case, the resin layers RIL may not protrude outward from the lower surface of the support part SUP even though the first area AA1 is rolled around the roller ROL so that the second openings OP2 are narrowed.

A protective film for protection of the substrate SUB may be disposed on the lower surface of the substrate SUB. The protective film may include polyethylene terephthalate (“PET”). The protective film may be attached to the lower surface of the substrate SB through an adhesive layer such as a pressure sensitive adhesive (“PSA”).

The above-described first opening OP1 may be defined in the protective film such that the bending area BA is more easily bent. When the protective film is used, a support part including support bars SB may be disposed under the protective film overlapping the first area AA1 to support the display panel DP. The first opening OP1 may not be defined in the support part. In this case, due to the use of the protective film and the adhesive layer, a process may be complicated, and the configuration of the display device may be complicated.

In an embodiment of the disclosure, the support part SUP may be directly attached to the lower surface of the display panel DP without the use of the protective film. Because the first opening OP1 and the second openings OP2 are defined together in the support part SUP, the bending area BA may be more easily bent, and the first area AA1 may be easily supported by the support bars SB. In addition, because the support bars SB and the resin layers RIL are disposed on the lower surface of the substrate SUB, the substrate SUB may be protected by the support bars SB and the resin layers RIL.

In an embodiment of the disclosure, the support part SUP may serve to support the substrate SUB while serving as the protective film, and thus the structure of the display device DD may be simplified. In addition, a process for providing the protective film may be omitted, and thus a manufacturing process of the display device DD may be simplified.

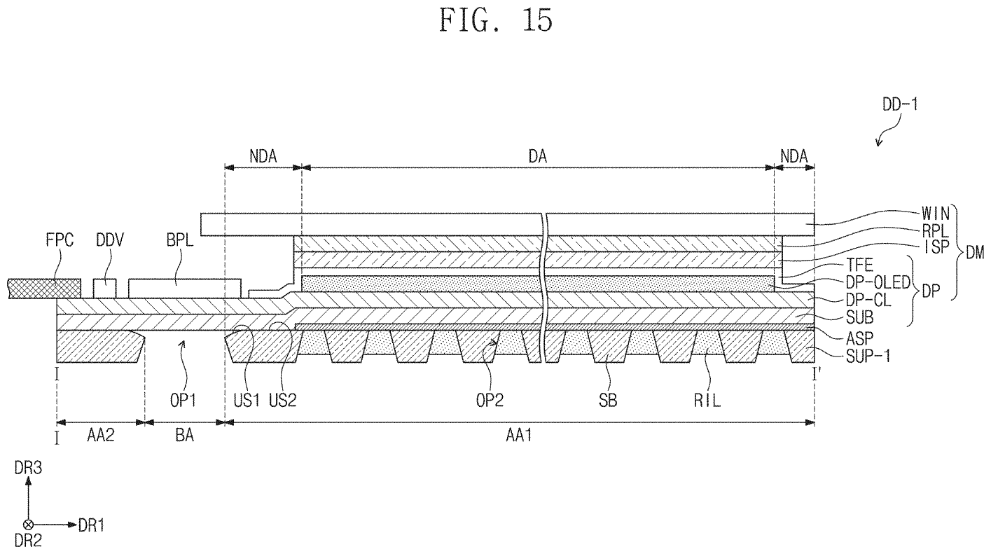

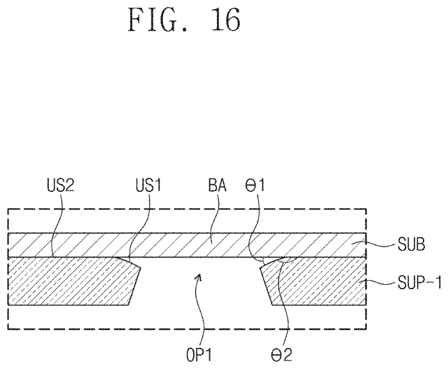

FIG. 15 is a view illustrating an embodiment of a configuration of a display device according to the disclosure. FIG. 16 is an enlarged view of a bending area and a portion of a support part under the bending area illustrated in FIG. 15.

The cross-sectional view of FIG. 15 corresponds to the cross-sectional view of FIG. 9. Hereinafter, the configuration of the display device DD-1 illustrated in FIG. 15 will be described. The following description will be focused on the difference between the configuration of the display device DD illustrated in FIG. 9 and the configuration of the display device DD-1 illustrated in FIG. 15, and components identical to the components illustrated in FIG. 9 will be assigned with identical reference numerals. Furthermore, the support part SUP-1 illustrated in FIG. 15 will be described as a structure including the support bars SB illustrated in FIG. 10.

Referring to FIGS. 15 and 16, the display device DD-1 may further include an auxiliary adhesive layer ASP disposed between a first area AA1 of a substrate SUB and the support part SUP-1. In an embodiment, the auxiliary adhesive layer ASP may include amorphous silicon (a-Si) or aluminum oxide, for example.

The auxiliary adhesive layer ASP may not be disposed on the lower surface of the bending area BA and the lower surface of a second area AA2. That is, the auxiliary adhesive layer ASP may be disposed only on the lower surface of the first area AA1 that overlaps the portion of the support part SUP-1 in which second openings OP2 are defined. A function of the auxiliary adhesive layer ASP will be described in detail in description of a manufacturing method.

The auxiliary adhesive layer ASP may strengthen the adhesive force between the substrate SUB and the support part SUP-1. The substrate SUB and the support part SUP-1 may be more firmly attached to each other when the auxiliary adhesive layer ASP, such as amorphous silicon (a-Si) or aluminum oxide, is disposed between the substrate SUB and the support part SUP-1.

Accordingly, the adhesive force between the substrate SUB and the support part SUP-1 when the auxiliary adhesive layer ASP is disposed between the substrate SUB and the support part SUP-1 may be greater than the adhesive force between the substrate SUB and the support part SUP-1 when the substrate SUB and the support part SUP-1 directly contact each other. The adhesive of the support part SUP-1 to the first area AA1 may be improved by the auxiliary adhesive layer ASP. The adhesive force of the support part SUP-1 to the bending area BA and the second area AA2 may be weaker than the adhesive force of the support part SUP-1 to the first area AA1.

When the bending area BA is unbent, the upper surface of the support part SUP-1 adjacent to a first opening OP1 may be spaced apart from the substrate SUB. When the bending area BA is bent, the upper surface of the support part SUP-1 adjacent to the first opening OP1 may contact the substrate SUB.

Specifically, the upper surface of the support part SUP-1 may include a first upper surface (also referred to as a first partial surface) US1 adjacent to the first opening OP1 and a second upper surface (also referred to as a second partial surface) US2 disposed around the first upper surface US1. Although two first upper surfaces US1 are substantially provided on the left and right sides of the first opening OP1 in FIG. 15, one first supper surface US1 will be described below for convenience of description. When the bending area BA is unbent, the first upper surface US1 may be spaced apart from the substrate SUB. The second upper surface US2 may contact the lower surface of the substrate SUB.

The first upper surface US1 may be inclined with respect to the second upper surface US2. In an embodiment, the first upper surface US1 may have a curved surface, for example. However, without being limited thereto, the first upper surface US1 may be formed to be a flat inclined surface. When the bending area BA is unbent, the first upper surface US1 may be spaced apart from the substrate SUB. The gap between the first upper surface US1 and the substrate SUB may be gradually increased away from the second upper surface US2. The first upper surface US1, when viewed in the second direction DR2, may have a curved shape. However, without being limited thereto, the first upper surface US1 may have the shape of a straight line.

In an embodiment, when the bending area BA is unbent, the first upper surface US1 may form a first angle θ1 greater than 0 degrees and smaller than or equal to 30 degrees with the lower surface of the substrate SUB, for example. Furthermore, the first upper surface US1 may form a second angle θ2 smaller than 180 degrees and greater than or equal to 150 degrees with the second upper surface US2.

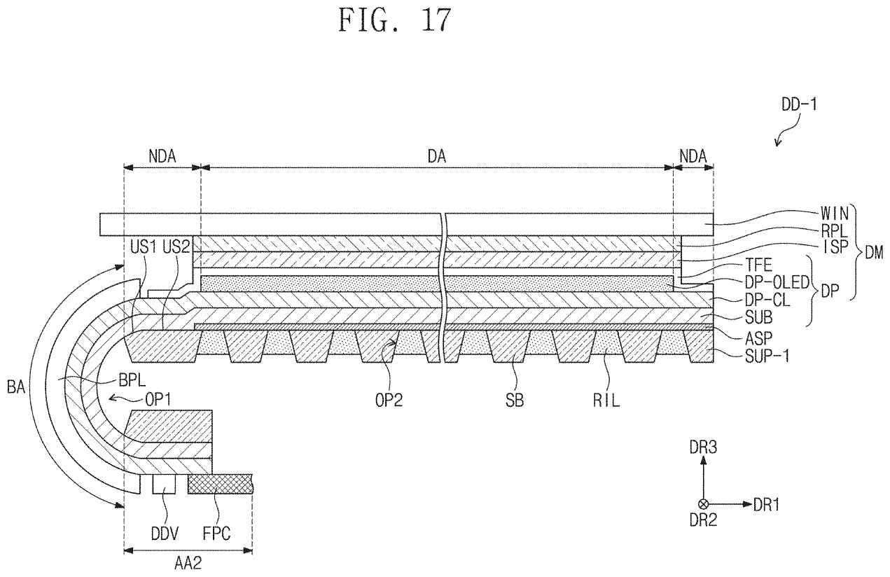

FIG. 17 is a view illustrating a state in which the bending area illustrated in FIG. 15 is bent.

Referring to FIG. 17, the bending area BA may be bent, and the second area AA2 may be disposed under the first area AA1. The bending area BA may be bent along the first upper surface US1 which is inclined. The first upper surface US1 may be disposed at a different height from a height of the second upper surface US2. The height may be defined as a numerical value measured in the third direction DR3. The second upper surface US2 may have a plane defined by the first and second directions DR1 and DR2, and the third direction DR3 may be defined as a direction perpendicular to the second upper surface US2.

The thickness of the portion of the support part SUP-1 that overlaps the first upper surface US1 may be gradually decreased toward the first opening OP1. In an embodiment, based on the third direction DR3, the gap between the first upper surface US1 and the lower surface of the support part SUP-1 that overlaps the first upper surface US1 may be gradually decreased toward the first opening OP1, for example.

When the bending area BA is bent, the substrate SUB may contact the first upper surface US1. The bending area BA may be bent while the substrate SUB contacts the first upper surface US1. When the first upper surface US1 is inclined as in FIG. 17, the bending area BA may be more easily bent along the first upper surface US1 than when the first upper surface US1 is flat as in FIG. 12.

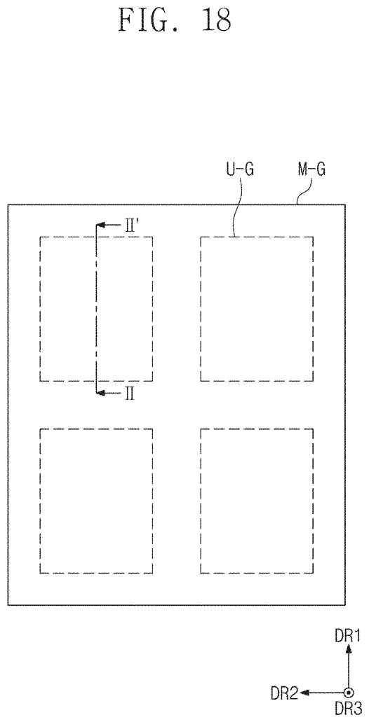

FIGS. 18 to 23 are views for describing a manufacturing method of the display device illustrated in FIG. 9.

Referring to FIG. 18, a mother substrate M-G for manufacturing the support part SUP may be prepared. The mother substrate M-G may include a plurality of unit substrates U-G. The unit substrates U-G may be cut to form the support part SUP.

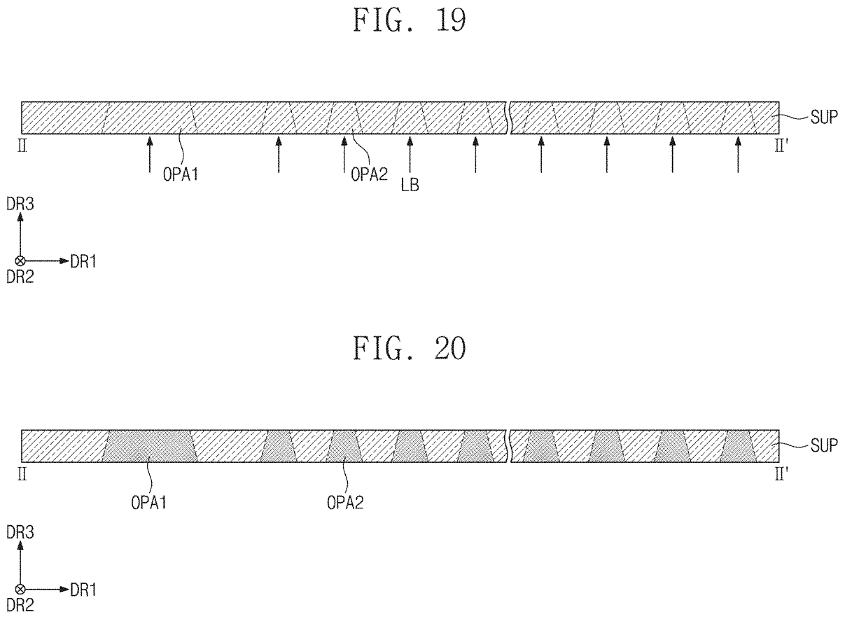

The following drawings are cross-sectional views taken along line II-II′ illustrated in FIG. 18. A process in which any one unit substrate U-G is processed to form the support part SUP will be described with reference to the cross-sectional views of FIGS. 19 to 23 taken along line II-II′. The unit substrate U-G in the cross-sectional views taken along line II-II′ may be also referred to as the support part SUP for convenience. The support part SUP illustrated in the manufacturing method will be described as including the support bars SB.

Referring to FIG. 19, the support part SUP may be prepared, and a first portion OPA1 and a plurality of second portions OPA2 may be defined in the support part SUP. The support part SUP illustrated in FIG. 19 may represent a state before the first and second openings OP1 and OP2 are defined.

The first portion OPA1 may correspond to the first opening OP1 illustrated in FIG. 9, and the second portions OPA2 may correspond to the second openings OP2 illustrated in FIG. 9. Substantially, the first and second portions OPA1 and OPA2 may be removed to define the first and second openings OP1 and OP2 illustrated in FIG. 9.

Referring to FIGS. 19 and 20, an intense light (e.g., a laser beam LB) may be applied to the first and second portions OPA1 and OPA2. The laser beam LB may include a picosecond laser beam or a femtosecond laser beam. The picosecond laser beam or the femtosecond laser beam may be defined as an ultrafast laser beam.

When a laser beam such as a picosecond laser beam or a femtosecond laser beam is applied to glass, physical properties of the glass may be changed. In an embodiment, when a laser beam such as a picosecond laser beam or a femtosecond laser beam is applied to glass, the bonding force between Si and O included in the glass may be weakened while photons are transformed into hot electrons, for example.

Physical properties of the first and second portions OPA1 and OPA2 may be changed by the laser beam LB applied to the first and second portions OPA1 and OPA2. The first and second portions OPA1 and OPA2 having the changed physical properties may more strongly react to an etchant such as hydrofluoric acid. Accordingly, the etch rate of the first and second portions OPA1 and OPA2 may be higher than the etch rate of other portions of the support part SUP.

In FIG. 20, the first and second portions OPA1 and OPA2 having the changed physical properties are illustrated with hatching different from the hatching drawn on the other portions of the support part SUP.

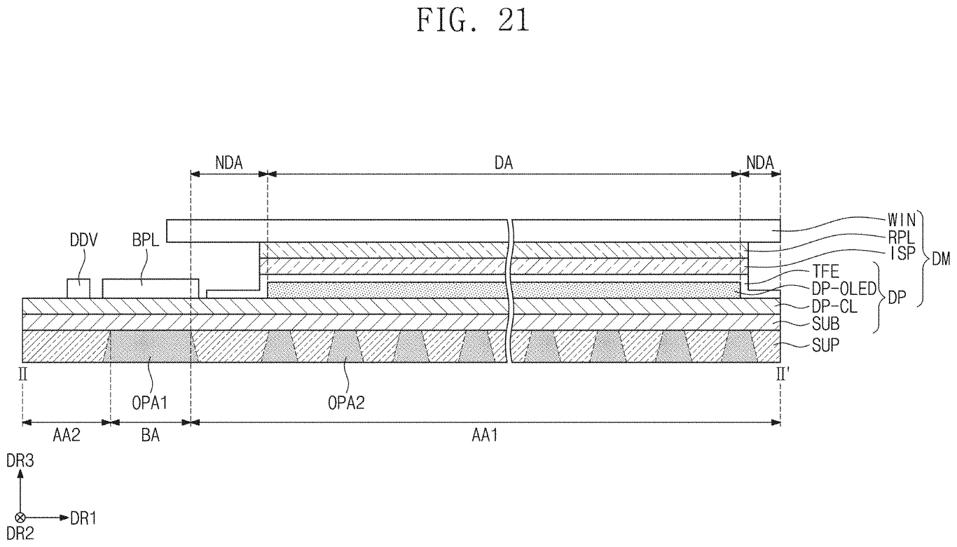

Referring to FIG. 21, the substrate SUB including the first area AA1, the bending area BA, and the second area AA2 may be provided on the support part SUP. The circuit element layer DP-CL and the display element layer DP-OLED may be provided on the substrate SUB. The light-emitting elements OLED disposed in the display element layer DP-OLED may be provided on the first area AA1, and the data driver DDV may be provided on the second area AA2.

The input sensing part ISP, the anti-reflection layer RPL, and the window WIN may be provided on the display panel DP.

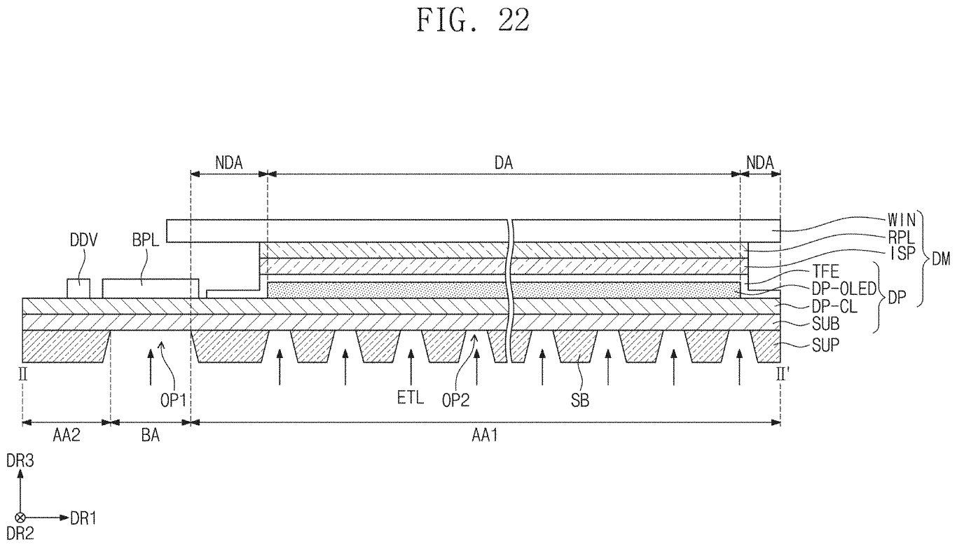

Referring to FIG. 22, an etchant ETL may be provided to the support part SUP. The etchant ETL may etch the support part SUP. As described above, the etch rate of the first and second portions OPA1 and OPA2 having the changed physical properties may be higher than the etch rate of the other portions of the support part SUP. Accordingly, even though the first and second portions OPA1 and OPA2 are removed first, the other portions of the support part SUP may remain without being removed.

The thickness of the other portions of the support part SUP may be decreased by the etchant ETL, but the other portions of the support part SUP may not be completely removed. The first opening OP1 overlapping the bending area BA and the second openings OP2 overlapping the first area AA1 may be defined in the support part SUP by the removal of the first and second portions OPA1 and OPA2 by the etchant ETL. The support bars SB may be formed by the second openings OP2.

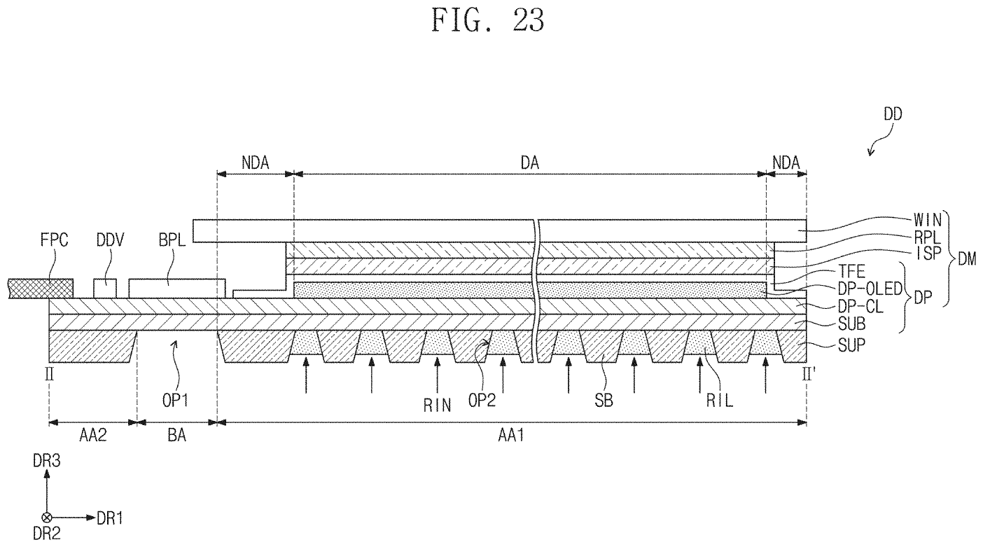

Referring to FIG. 23, a resin RIN having fluidity may be provided and cured in the second openings OP2. The resin layers RIL may be provided in the second openings OP2 by curing the resin RIN. The resin layers RIL may be provided in the second openings OP2 through an inkjet printing method. However, a method of providing the resin layers RIL in the second openings OP2 is not limited thereto.

The circuit board FPC may be connected to one side of the second area AA2. Thereafter, the bending area BA overlapping the first opening OP1 may be bent such that the second area AA2 is disposed under the first area AA1 as illustrated in FIG. 12, and the display device DD may be manufactured.

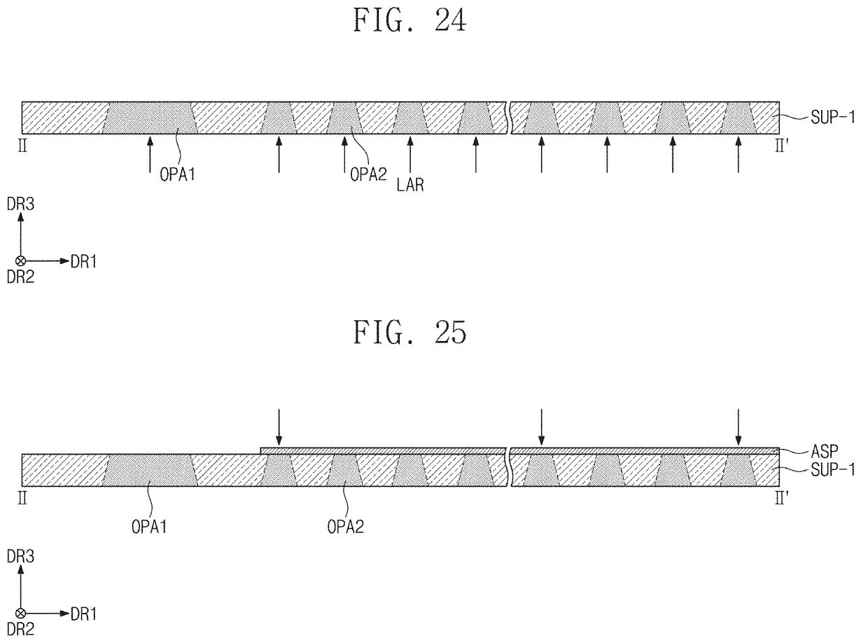

FIGS. 24 to 28 are views for describing a manufacturing method of the display device illustrated in FIG. 15.

Hereinafter, the manufacturing method of the display device DD-1 illustrated in FIGS. 24 to 28 will be described, and the following description will be focused on the difference between the manufacturing method of the display device DD illustrated in FIGS. 19 to 23 and the manufacturing method of the display device DD-1 illustrated in FIGS. 24 to 28. The support part SUP-1 illustrated in the manufacturing method will be described as including the support bars SB.

Referring to FIG. 24, a laser beam LAR may be applied to first and second portions OPA1 and OPA2 defined in the support part SUP-1 to change physical properties of the first and second portions OPA1 and OPA2.

Referring to FIG. 25, the auxiliary adhesive layer ASP may be provided on the support part SUP-1. The auxiliary adhesive layer ASP may be provided on the upper surface of the support part SUP-1 that overlaps the first area AA1 of the above-described substrate SUB. The auxiliary adhesive layer ASP may be disposed on the upper surface of the support part SUP-1 to cover the second portions OPA2.

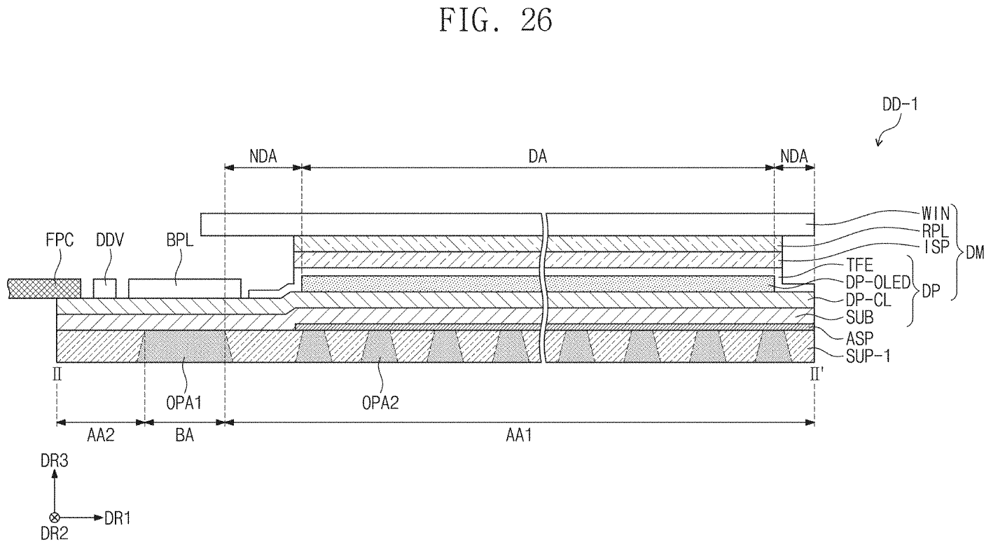

Referring to FIG. 26, the display panel DP, the input sensing part ISP, the anti-reflection layer RPL, and the window WIN may be provided on the support part SUP-1.

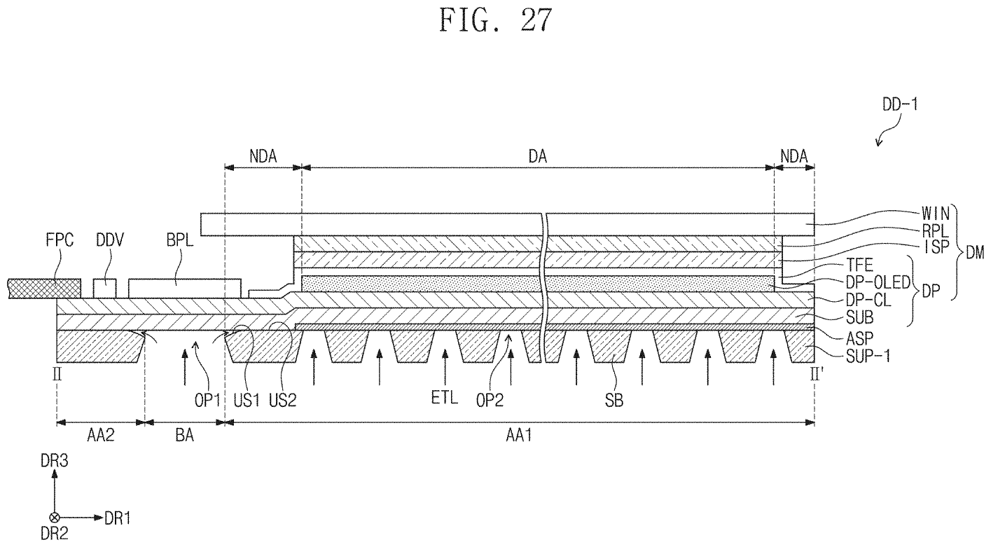

Referring to FIG. 27, an etchant ETL may be provided to the first and second portions OPA1 and OPA2 to remove the first and second portions OPA1 and OPA2. The first and second openings OP1 and OP2 may be defined in the support part SUP-1 by the removal of the first and second portions OPA1 and OPA2.

The adhesive force between the first area AA1 of the substrate SUB and the support part SUP-1 may be strengthened by the auxiliary adhesive layer ASP. However, as described above, the adhesive force of the support part SUP-1 to the bending area BA may be weaker than the adhesive force of the support part SUP-1 to the first area AA1.

In this case, through the first opening OP1, the etchant ETL may infiltrate between the substrate SUB and the support part SUP-1 that are adjacent to the first opening OP1. Accordingly, a portion of the upper surface of the support part SUP-1 adjacent to the first opening OP1 may be removed to define the above-described first upper surface US1. This structure may be defined as an undercut structure. The second upper surface US2, which is a portion where the etchant ETL does not infiltrate, may contact the lower surface of the substrate SUB.

The adhesive force of the support part SUP-1 to the first area AA1 may be strengthened by the auxiliary adhesive layer ASP, and thus the etchant ETL may fail to infiltrate between the substrate SUB and the support part SUP-1 through the second openings OP2. Accordingly, an undercut structure may not be formed on the support part SUP-1 under the first area AA1.

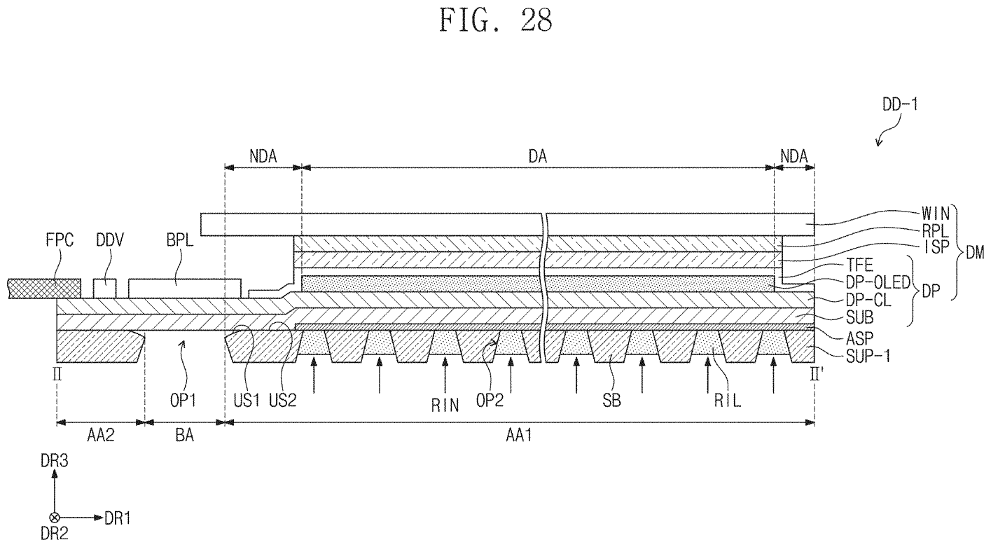

Referring to FIG. 28, the reins layers RIL may be provided in the second openings OP2 by curing a resin RIN provided in the second openings OP2. The circuit board FPC may be connected to one side of the second area AA2. Thereafter, the bending area BA overlapping the first opening OP1 may be bent such that the second area AA2 is disposed under the first area AA1 as illustrated in FIG. 17, and the display device DD-1 may be manufactured. The bending area BA may be easily bent by the first upper surface US1 formed by the etchant ETL.

By the embodiments of the disclosure, the support part may be directly attached to the lower surface of the display panel without the use of a protective film that protects the bottom of the substrate, and thus the structure of the display device may be simplified. Furthermore, a process for providing a protective film may be omitted, and thus a process of manufacturing the display device may be simplified.

In addition, the first opening overlapping the bending area of the substrate and the plurality of second openings overlapping the first area of the substrate that is rolled or unrolled may be defined in the support part. Thus, the bending area of the display panel may be easily bent, the lower surface of the display panel may be protected by the support part, and the portion of the support part under the first area may be easily rolled or unrolled.

While the disclosure has been described with reference to embodiments thereof, it will be apparent to those of ordinary skill in the art that various changes and modifications may be made thereto without departing from the spirit and scope of the disclosure as set forth in the following claims.

What is claimed is:

1. A display device comprising:
a substrate including a first area, a second area, and a bending area between the first area and the second area;
a light-emitting element disposed on the first area;
a driver disposed on the second area; and
a support part which is disposed under the substrate and in which a first opening and a plurality of second openings are defined,
wherein the first opening overlaps the bending area, and the plurality of second openings overlaps the first area.

2. The display device of claim 1, further comprising:
a resin layer disposed in each of the plurality of second openings.

3. The display device of claim 2, wherein the resin layer includes a first surface facing the substrate and a second surface opposite to the first surface of the resin layer,
wherein the support part includes a first surface facing the substrate and a second surface opposite to the first surface of the support part, and
wherein the second surface of the resin layer is closer to the substrate than the second surface of the support part.

4. The display device of claim 1, wherein the support part is directly attached to the substrate.

5. The display device of claim 1, wherein the bending area is bent such that the second area is disposed under the first area.

6. The display device of claim 5, wherein the first area is rolled and unrolled.

7. The display device of claim 1, wherein the plurality of second openings is arranged in a first direction and extend in a second direction crossing the first direction, and
wherein the support part includes a plurality of support bars separated from each other by the plurality of second openings and overlapping the first area.

8. The display device of claim 1, wherein the plurality of second openings includes:
a plurality of first sub-openings arranged in an h^{th} row where h is a natural number; and
a plurality of second sub-openings arranged in an (h+1)^{th} row and staggered with respect to the plurality of first sub-openings.

9. The display device of claim 1, wherein the support part includes a surface facing the substrate and including:
a first partial surface adjacent to the first opening; and
a second partial surface disposed around the first partial surface, and
wherein the first partial surface is disposed at a different height from a height of the second partial surface.

10. The display device of claim 9, wherein the support part includes a first surface facing the substrate and a second surface opposite to the first surface of the support part, and
Wherein a gap between the first partial surface and the second surface of the support part is gradually decreased toward the first opening.

11. The display device of claim 9, wherein the substrate contacts the first partial surface.

12. The display device of claim 1, further comprising:
an auxiliary adhesive layer disposed between the first area and the support part.

13. The display device of claim 12, wherein the auxiliary adhesive layer includes amorphous silicon or aluminum oxide.

14. A display device comprising:
a substrate including a first area, a second area, and a bending area between the first area and the second area;
a pixel disposed on the first area;
a driver disposed on the second area; and
a support part which is disposed under the substrate and in which a first opening overlapping the bending area is defined, the support part including:
a surface facing the substrate and including:
a first partial surface adjacent to the first opening; and
a second partial surface around the first partial surface,
wherein the first partial surface of the support part is inclined with respect to the second partial surface around the first partial surface.

15. A method for manufacturing a display device, the method comprising:
changing physical properties of a first portion and a plurality of second portions of a support part;
providing a substrate on the support part;
providing a pixel on an area of the substrate overlapping the plurality of second portions; and
defining a first opening and a plurality of second openings in the support part by removing the first portion and the plurality of second portions.

16. The method of claim 15, wherein the changing the physical properties of the first portion and the plurality of second portions includes changing the physical properties of the first portion and the plurality of second portions by applying an intense light to the first portion and the plurality of second portions, and
wherein the intense light includes a picosecond laser beam or a femtosecond laser beam.

17. The method of claim 15, further comprising:
providing a resin layer in each of the plurality of second openings; and
bending a bending area of the substrate overlapping the first opening,
wherein the resin layer includes a first surface facing the substrate and a second surface opposite to the first surface of the resin layer,
wherein the support part includes a first surface facing the substrate and a second surface opposite to the first surface of the support part, and
wherein the second surface of the resin layer is closer to the substrate than the second surface of the support part.

18. The method of claim 15, wherein the support part includes a plurality of support bars separated from each other by the plurality of second openings.

19. The method of claim 15, wherein the support part includes a surface facing the substrate, and
wherein the method further comprises:
removing a portion of the surface of the support part adjacent to the first opening,
wherein the first surface of the support part includes:
a first partial surface formed by removing the portion of the surface of the support part adjacent to the first opening; and
a second partial surface disposed around the first partial surface, and
wherein the first partial surface is disposed at a different height from a height the second partial surface.

20. The method of claim 15, further comprising:
providing an auxiliary adhesive layer on an upper surface of the support part to cover the plurality of second portions.
